(19) United States
(12) Patent Application Publication
(10) Pub. No.: US 2024/0352177 A1
(43) Pub. Date: Oct. 24, 2024

(54) CURABLE COMPOSITION, CURED PRODUCT THEREOF, AND PIEZOELECTRIC ELEMENT

(71) Applicant: Resonac Corporation, Minato-ku, Tokyo (JP)

(72) Inventors: Yutaka OKADA, Minato-ku, Tokyo (JP); Naoki FURUKAWA, Minato-ku, Tokyo (JP); Hiroshi YOKOTA, Minato-ku, Tokyo (JP)

(21) Appl. No.: 18/686,436

(22) PCT Filed: Aug. 26, 2022
(86) PCT No.: PCT/JP2022/032287

§ 371 Date: Feb. 26, 2024

(30) Foreign Application Priority Data
Aug. 30, 2021 (JP) 2021-139907
Oct. 8, 2021 (JP) 2021-166019

(51) Int. Cl. C08F 299/00; C08F 2/44; C08K 3/22; C08K 3/26

(52) U.S. Cl. CPC C08F 299/00; C08F 2/44; C08K 3/26; C08K 2003/2237; C08K 2201/001

(57) ABSTRACT

A curable composition containing piezoelectric particles and a compound represented by the following formula (1):

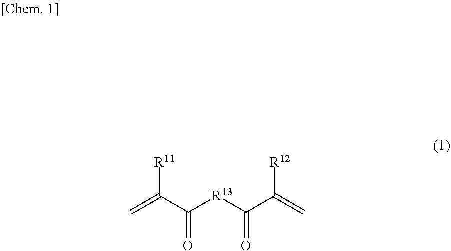

wherein R¹¹ and R¹² each independently represent a hydrogen atom or a methyl group, and R¹³ represents a divalent group having a polyoxyalkylene chain.

### TECHNICAL FIELD

The present disclosure relates to a curable composition, a cured product thereof, and a piezoelectric element.

### BACKGROUND ART

In recent years, piezoelectric elements are widely used for haptics applications, speaker applications, and the like. Piezoelectric elements may be required to have pliability (flexibility) depending on use applications. In such a case, for example, a piezoelectric film produced by dispersing piezoelectric particles in a polymer material and shaping the dispersion into a film shape, is used. For example, Patent Literature 1 discloses a polymer composite piezoelectric body in which piezoelectric particles are dispersed in a matrix formed of a polymer material, in which the piezoelectric particles contain 5 vol % or more and 30 vol % or less of particles having a particle diameter of 0.25 times or more and 1 time or less the film thickness of the polymer piezoelectric body.

### CITATION LIST

### Patent Literature

Patent Literature 1: Japanese Unexamined Patent Publication No. 2015-192120

### SUMMARY OF INVENTION

### Technical Problem

With regard to the polymer composite piezoelectric body described in the above-described Patent Literature 1, for example, in order to further improve the piezoelectric characteristics, it may be considered to increase the content of the piezoelectric particles; however, as the content of the piezoelectric particles increases, the polymer composite piezoelectric body becomes brittle as well as hard, and pliability is impaired. As described above, with regard to polymer composite piezoelectric bodies, compositions suitable for piezoelectric elements have not been sufficiently studied, and there is room for improvement.

Thus, an object of one aspect of the present invention is to provide a curable composition capable of forming a cured product having excellent pliability even when the content of piezoelectric particles is increased.

### Solution to Problem

The inventors of the present invention have found that a curable composition in which a specific bifunctional monomer having a polyoxyalkylene chain and piezoelectric particles are used in combination, is capable of forming a cured product having excellent pliability even when the content of the piezoelectric particles is increased. The present invention includes the following aspects.
[1] A curable composition containing piezoelectric particles and a compound represented by the following formula (1):

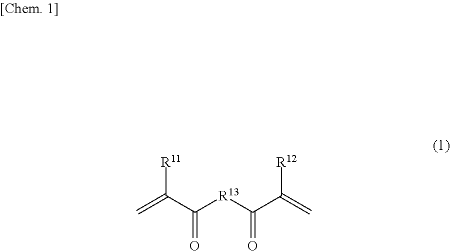

wherein R¹¹ and R¹² each independently represent a hydrogen atom or a methyl group, and R¹³ represents a divalent group having a polyoxyalkylene chain.
[2] The curable composition according to [1], wherein a content of the piezoelectric particles is 35% by volume or more based on a total amount of the curable composition.
[3] The curable composition according to [1] or [2], wherein the polyoxyalkylene chain contains an oxyethylene group.
[4] The curable composition according to [1] or [2], wherein the polyoxyalkylene chain contains an oxypropylene group.
[5] The curable composition according to [1] or [2], wherein the polyoxyalkylene chain is a copolymer chain containing an oxyethylene group and an oxypropylene group.
[6] The curable composition according to [5], wherein the copolymer chain is a random copolymer chain.
[7] The curable composition according to any one of [1] to [6], wherein the compound represented by formula (1) has a weight average molecular weight of 5000 or more.
[8] The curable composition according to any one of [1] to [7], wherein the compound represented by formula (1) has a viscosity at 25° C. of 1000 Pa·s or lower.
[9] The curable composition according to any one of [1] to [8], further containing a compound represented by the following formula (2):

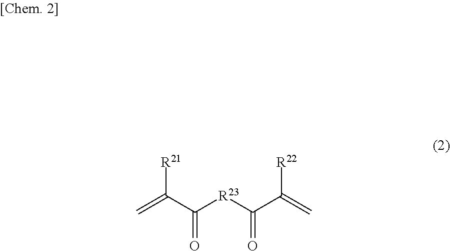

wherein R²¹ and R²² each independently represent a hydrogen atom or a methyl group, and R²³ represents a divalent group having a poly (meth) acrylate chain.
[10] The curable composition according to any one of [1] to [9], further containing a compound represented by the following formula (3):

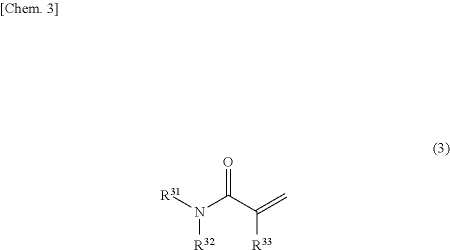

wherein R³¹ and R³² each independently represent a hydrogen atom or a monovalent organic group and may be bonded to each other to form a ring, and R³³ represents a hydrogen atom or a methyl group.
[11] A cured product of the curable composition according to any one of [1] to [10].
[12] A piezoelectric element containing the cured product according to [11].

### Advantageous Effects of Invention

According to one aspect of the present invention, a curable composition capable of forming a cured product having excellent pliability even when the content of piezoelectric particles is increased. In one aspect, this curable composition is capable of forming a cured product suitable for use in piezoelectric elements. Specifically, the cured product of the curable composition of one aspect can suppress deterioration of piezoelectric characteristics even when subjected to a high-temperature environment.

### DESCRIPTION OF EMBODIMENTS

Embodiments of the present invention will be described in detail below. Meanwhile, the present invention is not limited to the following embodiments.

The term “(meth)acryloyl” in the present specification means “acryloyl” and “methacryloyl” corresponding thereto, and the same also applies to similar expressions such as “(meth)acrylate” and “(meth)acryl”. The weight average molecular weight (Mw) and the ratio of the

weight average molecular weight and the number average molecular weight (Mw/Mn) in the present specification mean values that are measured by using gel permeation chromatography (GPC) under the following conditions and determined by using polystyrene as a standard material.
Measurement instrument: HLC-8320GPC (product name, manufactured by Tosoh Corporation)
Analytical column: TSKgel SuperMultipore HZ-H (three columns connected) (product name, manufactured by Tosoh Corporation)
Guard column: TSKguardcolumn SuperMP (HZ)-H (product name, manufactured by Tosoh Corporation)
Eluent: THF
Measurement temperature: 25° C.

A curable composition according to an embodiment of the present invention contains piezoelectric particles. The piezoelectric particles may be, for example, ceramic particles having a perovskite-type or wurtzite-type crystal structure. Examples of the ceramic constituting the piezoelectric particles include barium titanate (BaTiO₃), lead zirconate titanate (PZT), lead lanthanum zirconate titanate (PLZT), zinc oxide (ZnO), and a solid solution (BFBT) of barium titanate and bismuth ferrite (BiFe₃).

The average particle diameter of the piezoelectric particles may be, for example, 0.05 μm or more, 0.1 μm or more, or 0.3 μm or more and may be 50 μm or less, 30 μm or less, or 20 μm or less. The average particle diameter of the piezoelectric particles is measured by a laser diffraction/scattering type particle diameter distribution analyzer (for example, LA-950V2 manufactured by HORIBA, Ltd.). The curable composition may contain two or more kinds of piezoelectric particles having different average particle diameters from each other.

The content of the piezoelectric particles may be, for example, 30% by volume or more based on the total amount of the curable composition. As this curable composition contains the compound represented by the formula (1) that will be described below, even in a case where the content of the piezoelectric particles is increased, it is possible to form a cured product having excellent pliability. Therefore, in order to further improve the piezoelectric characteristics, the content of the piezoelectric particles may be 35% by volume or more, 40% by volume or more, 50% by volume or more, 55% by volume or more, 60% by volume or more, or 65% by volume or more, based on the total amount of the curable composition. The content of the piezoelectric particles may be, for example, 80% by volume or less or 70% by volume or less, based on the total amount of the curable composition.

The curable composition contains, in addition to the piezoelectric particles, a compound represented by the following formula (1):

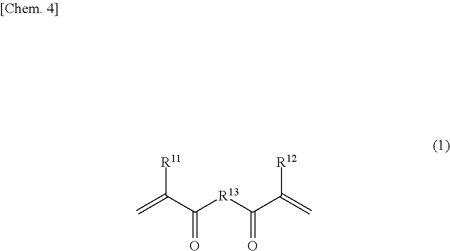

wherein R¹¹ and R¹² each independently represent a hydrogen atom or a methyl group, and R¹³ represents a divalent group having a polyoxyalkylene chain.

According to an embodiment, one of R¹¹ and R¹² may be a hydrogen atom while the other may be a methyl group, according to another embodiment, both R¹¹ and R¹² may be hydrogen atoms, and according to another embodiment, both R¹¹ and R¹² may be methyl groups.

According to an embodiment, the polyoxyalkylene chain contains a structural unit represented by the following formula (1a). As a result, the strength of the cured product can be increased while suppressing an excessive increase in the viscosity of the curable composition.

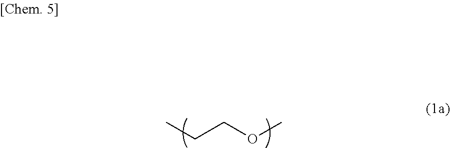

In this case, R¹³ may be a divalent group having a polyoxyethylene chain, and the compound represented by the formula (1) is preferably a compound represented by the following formula (1-2) (polyethylene glycol di(meth)acrylate):

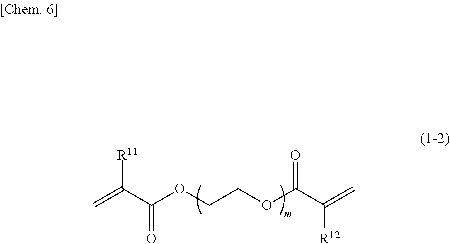

wherein R¹¹ and R¹² have the same meanings as R¹¹ and R¹² in the formula (1), respectively, and m is an integer of 2 or more.

According to another embodiment, the polyoxyalkylene chain contains a structural unit represented by the following formula (1b). As a result, handling of the curable composition can be facilitated.

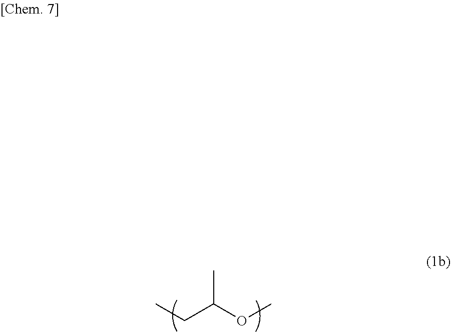

In this case, R¹³ may be a divalent group having a polyoxypropylene chain, and the compound represented by the formula (1) is preferably a compound represented by the following formula (1-3) (polypropylene glycol di(meth)acrylate):

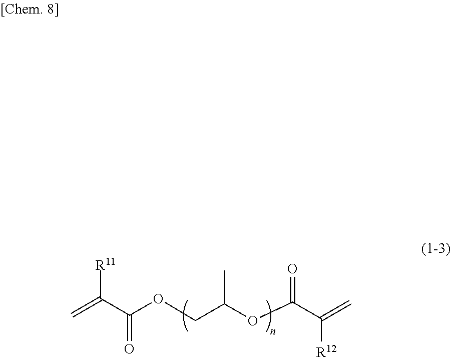

wherein R¹¹ and R¹² have the same meanings as R¹¹ and R¹² in the formula (1), respectively, and n is an integer of 2 or more.

According to another embodiment, from the viewpoint of making it easier to achieve both the strength of a cured product of the compound represented by the formula (1) and the handleability of the curable composition, the polyoxyalkylene chain is preferably a copolymer chain containing the above-mentioned structural unit represented by the formula (1a) and the above-mentioned structural unit represented by the formula (1b). The copolymer chain may be any of an alternating copolymer chain, a block copolymer chain, or a random copolymer chain. From the viewpoint of further lowering the crystallinity of the compound represented by the formula (1) and further facilitating handling of the curable composition, the copolymer chain is preferably a random copolymer chain.

In each of the above-mentioned embodiments, the polyoxyalkylene chain may have an oxyalkylene group having 4 to 5 carbon atoms, such as an oxytetramethylene group, an oxybutylene group, or an oxypentylene group, as a structural unit in addition to the structural unit represented by the formula (1a) and the structural unit represented by the formula ( 1b).

R¹³ may also be a divalent group further having another organic group in addition to the above-mentioned polyoxyalkylene chain. The other organic group may be a chain-like group other than a polyoxyalkylene chain and may be, for example, a methylene chain (chain having —CH₂— as a structural unit), a polyester chain (chain having —COO— in the structural unit), a polyurethane chain (chain having —OCON— in the structural unit), or the like.

For example, the compound represented by the formula (1) may be a compound represented by the following formula (1-4).

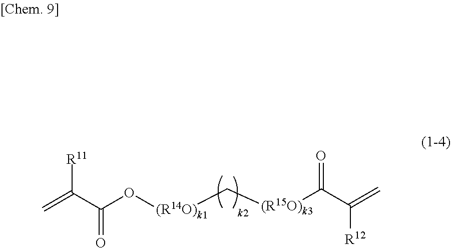

wherein R¹¹ and R¹² have the same meanings as R¹¹ and R¹² in the formula (1), respectively; R¹⁴ and R¹⁵ each independently represent an alkylene group having 2 to 5 carbon atoms; and k1, k2, and k3 each independently represent an integer of 2 or more. k2 may be, for example, an integer of 16 or less.

A plurality of R¹⁴ and a plurality of R¹⁵ may be respectively identical with each other or different from each other. The plurality of R¹⁴ and the plurality of R¹⁵ preferably contain an ethylene group and a propylene group, respectively. That is, the polyoxyalkylene chain represented by (R¹⁴O)ₖ₁ and the polyoxyalkylene chain represented by (R¹⁵O)ₖ₃ are preferably copolymer chains containing an oxyethylene group (structural unit represented by the above-described formula (1a)) and an oxypropylene group (structural unit represented by the above-described formula (1b)), respectively.

In each of the above-described embodiments, the number of oxyalkylene groups in the polyoxyalkylene chain is preferably 100 or more. When the number of oxyalkylene groups in the polyoxyalkylene chain is 100 or more, the main chain of the compound represented by the formula (1) becomes longer, and thereby elongation of the cured product becomes more excellent, while the strength of the cured product can also be increased. The number of oxyalkylene groups corresponds to m in formula (1-2), n in formula (1-3), and k1 and k3 in formula (1-4).

The number of oxyalkylene groups in the polyoxyalkylene chain is more preferably 130 or more, 180 or more, 200 or more, 220 or more, 250 or more, 270 or more, 300 or more, or 320 or more. The number of oxyalkylene groups in the polyoxyalkylene chain may be 600 or less, 570 or less, or 530 or less.

From the viewpoint that the cured product has lower elasticity and excellent elongation, the weight average molecular weight of the compound represented by the formula (1) is preferably 5000 or more, 6000 or more, 7000 or more, 8000 or more, 9000 or more, 10000 or more, 11000 or more, 12000 or more, 13000 or more, 14000 or more, or 15000 or more. From the viewpoint of easily adjusting the viscosity of the curable composition, the weight average molecular weight of the compound represented by the formula (1) is preferably 100000 or less, 80000 or less, 60000 or less, 34000 or less, 31000 or less, or 28000 or less.

The compound represented by the formula (1) may be liquid at 25° C. In this case, from the viewpoint of facilitating application on the coating surface and from the viewpoint of increasing the close adhesion of the cured product to the coating surface, the viscosity at 25° C. of the compound represented by the formula (1) is preferably 1000 Pa·s or lower, 800 Pa·s or lower, 600 Pa·s or lower, 500 Pa·s or lower, 350 Pa·s or lower, 300 Pa·s or lower, or 200 Pa·s or lower. The viscosity at 25° C. of the compound represented by the formula (1) may be 0.1 Pa·s or higher, 0.2 Pa·s or higher, 0.3 Pa·s or higher, 1 Pa·s or higher, 2 Pa·s or higher, or 3 Pa·s or higher.

The compound represented by the formula (1) may be solid at 25° C. In this case, from the viewpoint of improving handleability of the curable composition, the compound represented by the formula (1) is preferably liquid at 50° C. Furthermore, in this case, from the viewpoint of further improving handleability of the curable composition, the viscosity at 50° C. of the compound represented by the formula (1) is preferably 100 Pa·s or lower, more preferably 50 Pa·s or lower, even more preferably 30 Pa·s or lower, and particularly preferably 20 Pa·s or lower. The viscosity at 50° C. of the compound represented by the formula (1) may be 0.1 Pa·s or higher, 0.2 Pa·s or higher, or 0.3 Pa·s or higher.

In the present specification, the viscosity means a value measured on the basis of JIS Z8803, and specifically means a value measured by using an E-type viscometer (for example, manufactured by Toki Sangyo Co., Ltd., PE-80L). Calibration of the viscometer can be performed on the basis of JIS Z8809-JS14000. The viscosity of the compound represented by the formula (1) can be adjusted by adjusting the weight average molecular weight of the compound.

From the viewpoint that the cured product has more excellent elongation, the content of the compound represented by the formula (1) is preferably 1% by mass or more, 1.5% by mass or more, 2% by mass or more, 2.5% by mass or more, or 3% by mass or more, based on the total amount of the curable composition, and the content may be, for example, 10% by mass or less, 7% by mass or less, or 5% by mass or less.

The curable composition may further contain an additional polymerizable compound other than the compound represented by the formula (1), in addition to the compound represented by the formula (1) as the polymerizable compound (the details will be described below). From the viewpoint that the cured product has more excellent elongation, the content of the compound represented by the formula (1) is preferably 5 parts by mass or more, 10 parts by mass or more, or 15 parts by mass or more, with respect to 100 parts by mass of the sum of the compound represented by the formula (1) and the additional polymerizable compound (hereinafter, referred to as “sum of contents of polymerizable components”), and the content may be, for example, 40 parts by mass or less, 30 parts by mass or less, or 20 parts by mass or less.

From the viewpoint of improving the heat resistance of the cured product, the curable composition may further contain a compound represented by the following formula (2):

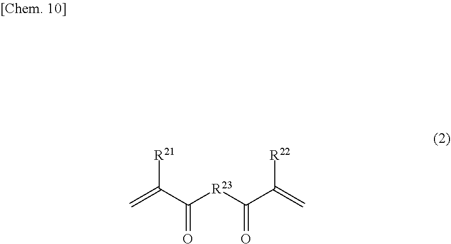

wherein R²¹ and R²² each independently represent a hydrogen atom or a methyl group, and R²³ represents a divalent group having a poly(meth)acrylate chain.

According to an embodiment, one of R²¹ and R²² may be a hydrogen atom while the other may be a methyl group, according to another embodiment, both R²¹ and R²² may be hydrogen atoms, and according to another embodiment, both R²¹ and R²² may be methyl groups.

The poly(meth)acrylate chain contains a structural unit represented by the following formula (2a):

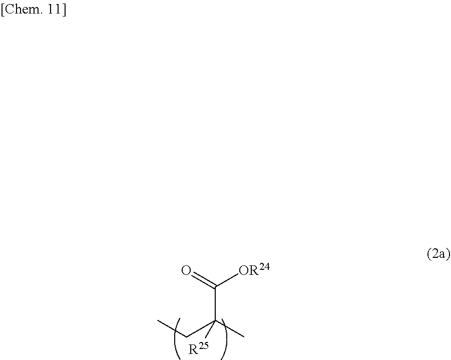

wherein R²⁴ represents a hydrogen atom or a monovalent organic group, and R²⁵ represents a hydrogen atom or a methyl group.

The monovalent organic group represented by R²⁴ may be, for example, a hydrocarbon group or may be an organic group having an oxygen atom, a nitrogen atom, or the like. The hydrocarbon group may be a chain-like group or may have a ring (for example, an aromatic ring). The number of carbon atoms of the hydrocarbon group may be, for example, 1 or more and may be 18 or less. Examples of the hydrocarbon group include a methyl group, an ethyl group, an n-propyl group, an isopropyl group, an n-butyl group, an isobutyl group, a t-butyl group, an n-pentyl group, an n-hexyl group, an n-heptyl group, an n-octyl group, a 2-ethylhexyl group, a 2-propylheptyl group, a nonyl group, a decyl group, an isodecyl group, a dodecyl group, an octadecyl group, a phenyl group, a toluyl group, and a benzyl group.

Examples of the organic group having an oxygen atom include a group having an alkoxy group, a group having a hydroxyl group, a group having a carboxyl group, and a group having a glycidyl group. Examples of the organic group having an oxygen atom include a 2-methoxyethyl group, a 3-methoxybutyl group, a 2-hydroxyethyl group, a 2-hydroxypropyl group, a 4-hydroxybutyl group, a carboxyl group, and a glycidyl group. Examples of the organic group having a nitrogen atom include groups having an amino group and a nitrile group. Examples of the organic group having a nitrogen atom include a 2-aminoethyl group and a nitrile group. According to an embodiment, the monovalent organic group represented by R²⁴ may be a group having a polar group or may be a group having a hydroxyl group or a carboxyl group.

For example, the compound represented by the formula (2) may be a compound represented by the following formula (2-2):

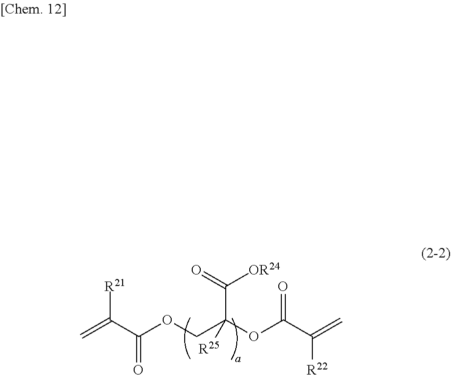

wherein R²¹ and R²² have the same meanings as R²¹ and R²² in formula (2), respectively; R²⁴ and R²⁵ have the same meanings as R²⁴ and R²⁵ in formula (2a), respectively; and a is an integer of 2 or more.

The weight average molecular weight of the compound represented by the formula (2) is preferably 3000 or more, 4000 or more, 5000 or more, 6000 or more, 7000 or more, 8000 or more, 9000 or more, 10000 or more, 11000 or more, 12000 or more, or 13000 or more. From the viewpoint of easily adjusting the viscosity of the curable composition, the weight average molecular weight of the compound represented by the formula (2) is preferably 100000 or less, 80000 or less, 60000 or less, 34000 or less, 31000 or less, or 28000 or less. a in formula (2a) may be an integer that the weight average molecular weight of the compound represented by the formula (2) is in the range such as described above.

The ratio (Mw/Mn) of the weight average molecular weight (Mw) and the number average molecular weight (Mn) of the compound represented by the formula (2) is preferably 1.4 or less or 1.2 or less.

The compound represented by the formula (2) may be liquid at 23° C. In this case, from the viewpoint of facilitating application on the coating surface and from the viewpoint of increasing close adhesion of the cured product to the coating surface, the viscosity at 23° C. of the compound represented by the formula (2) is 1000 Pa·s or lower, 800 Pa·s or lower, 700 Pa·s or lower, 600 Pa·s or lower, or 550 Pa·s or lower. The viscosity at 25° C. of the compound represented by the formula (2) may be 5 Pa·s or higher, 10 Pa·s or higher, 15 Pa·s or higher, 20 Pa·s or higher, 25 Pa·s or higher, 30 Pa·s or higher, or 35 Pa·s or higher.

The glass transition temperature (Tg) of the compound represented by the formula (2) may be 0° C. or lower, −10° C. or lower, or −30° C. or lower, and may be −60° C. or higher, −50° C. or higher, or −40° C. or higher. The glass transition temperature means a value measured by differential scanning calorimetry.

From the viewpoint of further improving heat resistance of the cured product, the content of the compound represented by the formula (2) is preferably 0.3% by mass or more, 0.5% by mass or more, or 1.0% by mass or more, and the content may be, for example, 10% by mass or less, 7% by mass or less, or 5% by mass or less, based on the total amount of the curable composition.

From the viewpoint that the cured product has more excellent heat resistance, the content of the compound represented by the formula (2) is preferably 3 parts by mass or more, 5 parts by mass or more, or 10 parts by mass or more, and the content may be, for example, 30 parts by mass or less, 20 parts by mass or less, or 15 parts by mass or less, with respect to 100 parts by mass of the sum of the contents of the polymerizable components.

From the viewpoint of further improving elongation and heat resistance of the cured product, the curable composition may further contain a compound represented by the following formula (3):

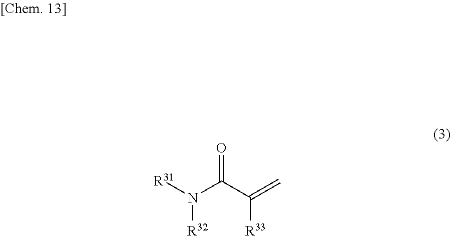

wherein R³¹ and R³² each independently represent a hydrogen atom or a monovalent organic group, and may be bonded to each other to form a ring. R³³ represents a hydrogen atom or a methyl group.

According to an embodiment, one of R³¹ and R³² may be a hydrogen atom while the other may be a monovalent organic group; according to another embodiment, both R³¹ and R³² may be hydrogen atoms; and according to another embodiment, both R³¹ and R³² may be monovalent organic groups that may be bonded to each other to form a ring.

In a case where R³¹ and R³² are not bonded to each other to form a ring, the monovalent organic group may be, for example, a monovalent hydrocarbon group or may be an alkyl group. The number of carbon atoms of the monovalent hydrocarbon group (alkyl group) may be 1 or more and may be 6 or less. Examples of the alkyl group include a methyl group, an ethyl group, an n-propyl group, and an isopropyl group. Examples of the compound represented by the formula (3) in a case where R³¹ and R³² are not bonded to each other to form a ring, include dimethylacrylamide, diethylacrylamide, and diisopropylacrylamide.

R³¹ and R³² are preferably bonded to each other to form a ring. In this case, this ring may be, for example, a 5-membered ring, a 6-membered ring, or a 7-membered ring, or the ring is preferably a 6-membered ring. This ring is formed by a nitrogen atom and the groups represented by R³¹ and R^{32,} and the ring may contain a carbon atom, a hydrogen atom, an oxygen atom, a sulfur atom, and the like in addition to the nitrogen atom, and preferably contains only a carbon atom, a hydrogen atom, and an oxygen atom. That is, the group represented by R³¹ and R³² may be a group containing a carbon atom, a hydrogen atom, an oxygen atom, a sulfur atom, and the like, and may be preferably a group containing only a carbon atom, a hydrogen atom, and an oxygen atom. Examples of the compound represented by the formula (3) in a case where R³¹ and R³² are bonded to each other to form a ring, include N-(meth)acryloylmorpholine, N-acryloylthiomorpholine, N-acryloyloxazoline, N-acryloylthiazolidine, N-acryloylimidazolidine, N-(meth)acryloylpiperazine, N-vinylpyrrolidone, and N-vinylcaprolactam.

From the viewpoint of further improving elongation and heat resistance of the cured product, the content of the compound represented by the formula (3) is preferably 0.1% by mass or more, 0.5% by mass or more, or 1% by mass or more, and the content may be, for example, 3% by mass or less, 2.5% by mass or less, or 2% by mass or less, based on the total amount of the curable composition.

From the viewpoint of further improving elongation and heat resistance of the cured product, the content of the compound represented by the formula (3) is preferably 1 part by mass or more, 5 parts by mass or more, or 7 parts by mass or more, and the content may be, for example, 30 parts by mass or less, 20 parts by mass or less, or 10 parts by mass or less, with respect to 100 parts by mass of the sum of the contents of the polymerizable component.

For the purpose of adjusting the physical properties of the curable composition, and the like, the curable composition may further contain an additional polymerizable compound that can be copolymerized with the compound represented by the formula (1), the compound represented by the formula (2), and the compound represented by the formula (3) mentioned above.

The additional polymerizable compound may be, for example, a compound having one (meth)acryloyl group other than the compound represented by the formula (3). This compound may be, for example, an alkyl (meth)acrylate. The additional polymerizable compound may be a compound having an aromatic hydrocarbon group, a group having a polyoxyalkylene chain, a group having a heterocyclic ring, an alkoxy group, a phenoxy group, a group having a silane group, a group having a siloxane bond, a halogen atom, a hydroxyl group, a carboxyl group, an amino group, or an epoxy group, in addition to one (meth)acryloyl group. Particularly, as the curable composition contains an alkyl (meth)acrylate, the viscosity of the curable composition can be adjusted. In addition, as the curable composition contains a compound having a hydroxyl group, a carboxyl group, an amino group, or an epoxy group in addition to a (meth)acryloyl group, the close adhesion of the curable composition and a cured product thereof to a member can be further improved.

The alkyl group in the alkyl (meth)acrylate (alkyl group moiety other than the (meth)acryloyl group) may be straight-chained, branched, or alicyclic. The number of carbon atoms of the alkyl group may be, for example, 1 to 30. The number of carbon atoms of the alkyl group may be 1 to 11, 1 to 8, 1 to 6, or 1 to 4, and may be 12 to 30, 12 to 28, 12 to 24, 12 to 22, 12 to 18, or 12 to 14.

Examples of the alkyl (meth)acrylate having a straight-chained alkyl group include alkyl (meth) acrylates having a straight-chained alkyl group with 1 to 11 carbon atoms, such as methyl (meth)acrylate, ethyl (meth)acrylate, propyl (meth)acrylate, butyl (meth)acrylate, pentyl (meth)acrylate, n-hexyl (meth)acrylate, n-heptyl methacrylate, octyl (meth)acrylate, nonyl (meth)acrylate, decyl (meth)acrylate, or undecyl (meth)acrylate; and alkyl (meth)acrylates having a straight-chained alkyl group with 12 to 30 carbon atoms, such as dodecyl (meth)acrylate (lauryl (meth)acrylate), tetradecyl (meth)acrylate, hexadecyl (meth)acrylate (cetyl (meth)acrylate), octadecyl (meth)acrylate (stearyl (meth)acrylate), docosyl (meth)acrylate (behenyl (meth)acrylate), tetracosyl (meth)acrylate, hexacosyl (meth)acrylate, and octacosyl (meth)acrylate.

Examples of the alkyl (meth)acrylate having a branched alkyl group include alkyl (meth)acrylates having a branched alkyl group with 1 to 11 carbon atoms, such as s-butyl (meth)acrylate, t-butyl (meth)acrylate, isobutyl (meth)acrylate, isopentyl (meth)acrylate, isoamyl (meth)acrylate, isooctyl (meth)acrylate 2-ethylhexyl (meth)acrylate, isononyl (meth)acrylate, and isodecyl (meth)acrylate; and alkyl (meth)acrylates having a branched alkyl group with 12 to 30 carbon atoms, such as isomyristyl (meth)acrylate, 2-propylheptyl (meth)acrylate, isoundecyl (meth)acrylate, isododecyl (meth)acrylate, isotridecyl (meth)acrylate, isopentadecyl (meth)acrylate, isohexadecyl (meth)acrylate, isoheptadecyl (meth)acrylate, isostearyl (meth)acrylate, and decyltetradecanyl (meth) acrylate.

Examples of the alkyl (meth) acrylate having an alicyclic alkyl group (cycloalkyl group) include cyclohexyl (meth) acrylate, 3,3,5-trimethylcyclohexyl (meth)acrylate, isobornyl (meth)acrylate, terpene (meth)acrylate, and dicyclopentanyl (meth)acrylate.

Examples of the compound having a (meth)acryloyl group and an aromatic hydrocarbon group include benzyl (meth)acrylate.

Examples of the compound having a (meth)acryloyl group and a group including a polyoxyalkylene chain include polyethylene glycol (meth)acrylate, methoxy polyethylene glycol (meth)acrylate, polypropylene glycol (meth)acrylate, methoxy polypropylene glycol (meth)acrylate, polybutylene glycol (meth)acrylate, and methoxy polybutylene glycol (meth)acrylate.

Examples of the compound having a (meth)acryloyl group and a group including a heterocyclic ring include tetrahydrofurfuryl (meth)acrylate.

Examples of the compound having a (meth)acryloyl group and an alkoxy group include 2-methoxyethyl acrylate.

Examples of the compound having a (meth)acryloyl group and a phenoxy group include phenoxyethyl (meth)acrylate.

Examples of the compound having a (meth)acryloyl group and a group including a silane group include 3-acryloxypropyltriethoxysilane, 10-methacryloyloxydecyltrimethoxysilane, 10-acryloyloxydecyltrimethoxysilane, 10-methacryloyloxydecyltriethoxysilane, and 10-acryloyloxydecyltriethoxysilane.

Examples of the compound having a (meth)acryloyl group and a group including a siloxane bond include silicone (meth)acrylate.

Examples of the compound having a (meth)acryloyl group and a halogen atom include (meth)acrylates having a fluorine atom, such as trifluoromethyl (meth)acrylate, 2,2,2-trifluorocthyl (meth)acrylate, 1,1,1,3,3,3-hexafluoro-2-propyl (meth)acrylate, perfluorocthylmethyl (meth)acrylate, perfluoropropylmethyl (meth)acrylate, perfluorobutylmethyl (meth)acrylate, perfluoropentylmethyl (meth)acrylate, perfluorohexylmethyl (meth)acrylate, perfluoroheptylmethyl (meth)acrylate, perfluorooctylmethyl (meth)acrylate, perfluorononylmethyl (meth)acrylate, perfluorodecylmethyl (meth)acrylate, perfluoroundecylmethyl (meth)acrylate, perfluorododecylmethyl (meth)acrylate, perfluorotridecylmethyl (meth)acrylate, perfluorotetradecylmethyl (meth)acrylate, 2-(trifluoromethyl)ethyl (meth)acrylate, 2-(perfluoroethyl)ethyl (meth)acrylate, 2-(perfluoropropyl)ethyl (meth)acrylate, 2-(perfluorobutyl)ethyl (meth)acrylate, 2-(perfluoropentyl)ethyl (meth)acrylate, 2-(perfluorohexyl)ethyl (meth)acrylate, 2-(perfluoroheptyl)ethyl (meth)acrylate, 2-(perfluorooctyl)ethyl (meth) acrylate, 2-(perfluorononyl) ethyl (meth) acrylate, 2-(perfluorotridecyl)ethyl (meth) acrylate, and 2-(perfluorotetradecyl)ethyl (meth)acrylate.

Examples of the compound having a (meth)acryloyl group and a hydroxyl group include hydroxyalkyl (meth)acrylates such as 2-hydroxyethyl (meth)acrylate, 2-hydroxypropyl (meth) acrylate, 3-hydroxypropyl (meth)acrylate, 2-hydroxybutyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, and 12-hydroxylauryl (meth)acrylate; and hydroxyalkylcycloalkane (meth)acrylates such as (4-hydroxymethylcyclohxeyl)methyl (meth)acrylate.

Examples of the compound having a (meth)acryloyl group and a carboxyl group include (meth)acrylic acid, carboxyethyl (meth)acrylate, carboxypentyl (meth)acrylate, monohydroxyethyl acrylate phthalate (for example, “ARONIX M5400” manufactured by TOAGOSEI CO., LTD.), and 2-acryloyloxyethyl succinate (for example, “NK ESTER A-SA” manufactured by SHIN-NAKAMURA CHEMICAL Co., Ltd.).

Examples of the compound having a (meth)acryloyl group and an amino group include N,N-dimethylaminoethyl (meth)acrylate, N,N-diethylaminoethyl (meth)acrylate, N,N-dimethylaminopropyl (meth)acrylate, and N,N-diethylaminopropyl (meth) acrylate.

Examples of the compound having a (meth)acryloyl group and an epoxy group include glycidyl (meth)acrylate, α-ethyl glycidyl (meth)acrylate, α-n-propyl glycidyl (meth)acrylate, α-n-butyl glycidyl (meth)acrylate, 3,4-epoxybutyl (meth)acrylate, 4,5-epoxypentyl (meth)acrylate, 6,7-epoxyheptyl (meth) acrylate, α-ethyl 6,7-epoxyhcptyl (meth)acrylate, 3-methyl-3,4-epoxybutyl (meth)acrylate, 4-methyl-4,5-epoxypentyl (meth)acrylate, 5-methyl-5,6-epoxyhexyl (meth)acrylate, β-methylglycidyl (meth)acrylate, and α-ethyl β-methylglycidyl (meth)acrylate.

From the viewpoint of easily adjusting the viscosity of the curable composition, or from the viewpoint of further increasing the close adhesion of the curable composition, the content of the additional polymerizable compound is preferably 2% by mass or more, 4% by mass or more, 6% by mass or more, 8% by mass or more, or 10% by mass or more, and the content may be, for example, 30% by mass or less, 20% by mass or less, or 15% by mass or less, based on the total amount of the curable composition.

From the viewpoint of easily adjusting the viscosity of the curable composition, or from the viewpoint of further increasing the close adhesion of the curable composition, the content of the additional polymerizable compound is preferably 40 parts by mass or more, 50 parts by mass or more, or 60 parts by mass or more, and the content may be, for example, 90 parts by mass or less, 80 parts by mass or less, or 70 parts by mass or less, with respect to 100 parts by mass of the sum of the contents of the polymerizable components.

The curable composition may further contain a polymerization initiator. The polymerization initiator may be, for example, a thermal polymerization initiator that generates radicals by heat, or a photopolymerization initiator that generates radicals by light. The polymerization initiator is preferably a thermal polymerization initiator.

In a case where the curable composition contains a thermal polymerization initiator, a cured product of the curable composition can be obtained by applying heat to the curable composition. In this case, the curable composition may be a curable composition that is cured by heating preferably at 105° C. or higher, more preferably 110° C. or higher, and even more preferably 115° C. or higher, and may be a curable composition that is cured by heating, for example, at 200° C. or lower, 190° C. or lower, or 180° C. or lower. The heating time at the time of heating the curable composition may be selected as appropriate according to the composition of the curable composition so that the curable composition is suitably cured.

Examples of the thermal polymerization initiator include azo compounds such as azobisisobutyronitrile, azobis-4-methoxy-2,4-dimethylvaleronitrile, azobiscyclohexanone-1-carbonitrile, and azodibenzoyl; and organic peroxides such as benzoyl peroxide, lauroyl peroxide, di-t-butyl peroxide, di-t-hexyl peroxide, di-t-butyl peroxyhexahydroterephthalate, t-butyl peroxy-2-ethylhexanoate, 1,1-t-butylperoxy-3,3,5-trimethylcyclohexane, and t-butylperoxyisopropyl carbonate. Regarding the thermal polymerization initiators, these may be used singly or in combination of two or more kinds thereof.

From the viewpoint of suitably allowing polymerization to proceed, the content of the polymerization initiator is preferably 0.01 parts by mass or more, more preferably 0.05 parts by mass or more, even more preferably 0.1 parts by mass or more, and particularly preferably 0.5 parts by mass or more, with respect to 100 parts by mass of the sum of the contents of the polymerizable components. From the viewpoint of keeping the molecular weight of the polymer in a cured product of the curable composition to be in a suitable range and also suppressing decomposition products, the content of the polymerization initiator is preferably 10 parts by mass or less, more preferably 5 parts by mass or less, and even more preferably 3 parts by mass or less, with respect to 100 parts by mass of the sum of the contents of the polymerizable components.

The curable composition may further contain a plasticizer. As the curable composition contains a plasticizer, the close adhesion of the curable composition and the elongation of the cured product can be further increased. Examples of the plasticizer include tackifiers such as butadiene rubber, isoprene rubber, silicon rubber, styrene-butadiene rubber, chloroprene rubber, nitrile rubber, butyl rubber, ethylene-propylene rubber, urethane rubber, an acrylic resin, a rosin-based resin, and a terpene-based resin; and a polyalkylene glycol.

The content of the plasticizer may be 0.1 parts by mass or more, 1 part by mass or more, or 3 parts by mass or more, and may be 20 parts by mass or less, 15 parts by mass or less, or 10 parts by mass or less, with respect to 100 parts by mass of the sum of the contents of the polymerizable components.

From the viewpoint of improving thermal reliability of the cured product, the curable composition may further contain an oxidation inhibitor. The oxidation inhibitor may be, for example, a phenol-based oxidation inhibitor, a benzophenone-based oxidation inhibitor, a benzoate-based oxidation inhibitor, a hindered amine-based oxidation inhibitor, or a benzotriazole-based oxidation inhibitor, and the oxidation inhibitor is preferably a phenol-based oxidation inhibitor.

A phenol-based oxidation inhibitor has, for example, a hindered phenol structure (hindered phenol ring). The hindered phenol structure (hindered phenol ring) may be, for example, a structure in which a t-butyl group is bonded to one position or both positions of the ortho-position with respect to the hydroxyl group in a phenol ring. A phenol-based oxidation inhibitor has one or more units of such a hindered phenol ring and preferably has two or more units, more preferably three or more units, and even more preferably four or more units, of the hindered phenol ring.

The content of the oxidation inhibitor may be 0.1% by mass or more, 0.2% by mass or more, or 0.3% by mass or more, and may be 5% by mass or less, 3% by mass or less, or 1% by mass or less, based on the total amount of the curable composition.

The curable composition may further contain additional additives as necessary. Examples of the additional additives include a surface treatment agent (for example, a silane coupling agent), a dispersant, a curing accelerator, a colorant, a crystal nucleating agent, a thermal stabilizer, a foaming agent, a flame retardant, a vibration damping agent, a dehydrating agent, and a flame retardant aid (for example, a metal oxide). The content of the additional additives may be 0.1% by mass or more and may be 10% by mass or less, based on the total amount of the curable composition.

The above-mentioned curable composition is used after being cured. That is, another embodiment of the present invention is a cured product of the above-mentioned curable composition. The cured product is obtained by, for example, heating the curable composition and/or irradiating the curable composition with light, depending on the type of the above-mentioned polymerization initiator.

The cured product may be, for example, in a sheet form. The thickness of the sheet-shaped cured product may be, for example, 10 μm or more, 30 μm or more, or 50 μm or more, and may be 2.0 mm or less, 1.0 mm or less, or 0.3 mm or less.

The cured product can be suitably used for piezoelectric elements. That is, another embodiment of the present invention is a piezoelectric element including the cured product. Since the cured product has excellent pliability (can suppress an increase in the tensile modulus) even in a case where the content of the piezoelectric particles is increased, the piezoelectric characteristics can be improved while ensuring pliability of a piezoelectric element. Furthermore, according to an embodiment, the cured product is excellent in terms of mechanical strength such as elongation at break and breaking strength.

In addition, according to an embodiment, the cured product can suppress deterioration of the piezoelectric characteristics even in a high-temperature environment. Therefore, a piezoelectric element containing the cured product can exhibit excellent piezoelectric characteristics even in a higher-temperature environment, as compared with piezoelectric elements containing conventional polymer materials (for example, a piezoelectric element containing PVDF).

Furthermore, for example, a piezoelectric element containing the cured product has excellent heat resistance. The 5% weight loss temperature of the cured product may be, for example, 250° C. or higher, 300° C. or higher, or 350° C. or higher. The weight loss ratio of the cured product after being maintained at 150° C. for 1 hour may be, for example, 1.0% by weight or less, 0.5% by weight or less, or 0.2% by weight or less. Incidentally, the 5% weight loss temperature and the weight loss ratio after being maintained at 150° C. for 1 hour are measured by the methods described in the Examples.

The piezoelectric element may be, for example, a piezoelectric element (a sensor or the like) that generates electric charges when an external force (pressure) is applied, or may be a piezoelectric element that generates a displacement when a voltage is applied (an actuator, an oscillator, or the like). The piezoelectric element may be used for, for example, haptics applications and speaker applications.

### EXAMPLES

The present invention will be described more specifically on the basis of Examples; however, the present invention is not intended to be limited to these Examples.

In the Examples, each of the following components was used.
A-1: Piezoelectric particles (barium titanate, PALCERAM BTE-UP (manufactured by NIPPON CHEMICAL INDUSTRIAL CO., LTD.), average particle diameter 14 μm)
A-2: Piezoelectric particles (barium titanate, PALCERAM BT-UP2 (manufactured by NIPPON CHEMICAL INDUSTRIAL CO., LTD.), average particle diameter 2 μm)
A-3: Piezoelectric particles (barium titanate, PALCERAM BTC-4FB (manufactured by NIPPON CHEMICAL INDUSTRIAL CO., LTD.), average particle diameter 0.4 μm)
B-1: Compound represented by the following formula (1-5):

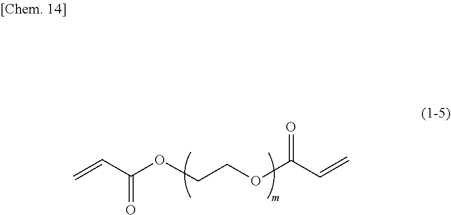

and synthesized by the procedure described below (weight average molecular weight: 8000, a mixture in which m in the formula (1-5) is an integer of approximately 180±3, viscosity at 50° C.: 10 Pa·s (solid at 25° C.)).
B-2: Compound represented by the formula (1-6):

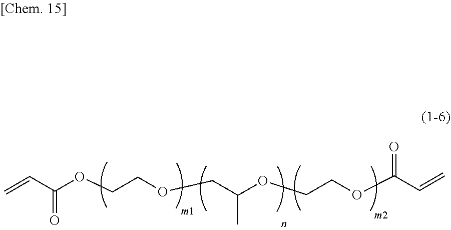

and synthesized by the procedure described below (weight average molecular weight: 9400, a mixture in which ml+m2 in the formula (1-6) is an integer of approximately 160±5, and n is an integer of approximately 38±5, viscosity at 50° C.: 8 Pa·s (solid at 25° C.)).

B-3: Compound represented by the formula (1-7):

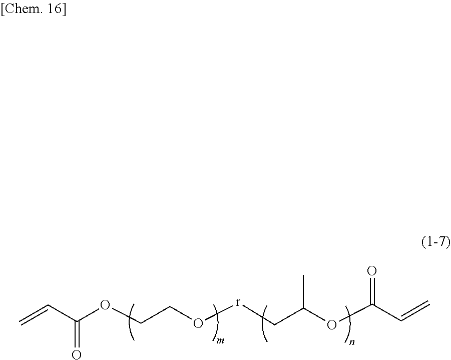

wherein -r- is a symbol representing random copolymerization, and synthesized by the procedure described below (weight average molecular weight: 16000, a mixture in which m in the formula (1-7) is approximately an integer of 246'5, and n is an integer of approximately 105±5, viscosity at 25° C.: 55 Pa·s).
C-1: Compound represented by the following formula (2-3):

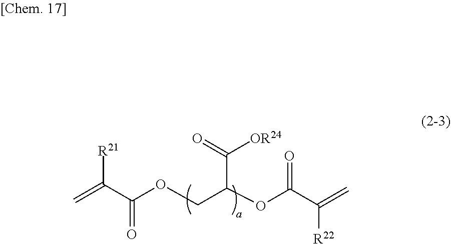

(RC100C, manufactured by KANEKA CORPORATION, weight average molecular weight: 24000, a compound in which R²¹ and R²² in the formula (2-3) are each a hydrogen atom or a methyl group, and R²⁴ is an alkyl group, viscosity at 23° C.: 160 Pa·s, Tg: −50° C.).
C-2: Compound represented by the above formula (2-3) (RC200C, manufactured by KANEKA CORPORATION, weight average molecular weight: 18000, a compound in which R²¹ and R²² in the formula (2-3) are each a hydrogen atom or a methyl group, and R²⁴ is a polar group, viscosity at 23° C.: 530 Pa·s, Tg: −39° C.). D-1: Hydroxybutyl acrylate (manufactured by OSAKA ORGANIC CHEMICAL INDUSTRY LTD.)
D-2:2-Acryloyloxyethylsuccinic acid (manufactured by SHIN-NAKAMURA CHEMICAL Co., Ltd.)
D-3: Acryloylmorpholine (manufactured by KJ Chemicals Corporation)
D-4: Isodecyl acrylate (manufactured by OSAKA ORGANIC CHEMICAL INDUSTRY LTD.)
D-5: Methoxy polyethylene glycol acrylate (AM-90G, manufactured by SHIN-NAKAMURA CHEMICAL Co., Ltd.)
D-6: Ethoxylated-o-phenylphenol acrylate (A-LEN-10, manufactured by SHIN-NAKAMURA CHEMICAL Co., Ltd.)
D-7: Urethane acrylate (UA-4200, manufactured by SHIN-NAKAMURA CHEMICAL Co., Ltd.)
D-8: Bifunctional polyethylene glycol acrylate (A-200, manufactured by SHIN-NAKAMURA CHEMICAL Co., Ltd.)
E-1: Plasticizer (rosin ester, KE359, Arakawa Chemical Industries, Ltd.)
F-1: Oxidation inhibitor (phenol-based oxidation inhibitor, AO-60, manufactured by ADEKA Corporation)
F-2: Oxidation inhibitor (phenol-based oxidation inhibitor, AO-80, manufactured by ADEKA Corporation)
G-1: Thermal polymerization initiator (PERBUTYL O, manufactured by NOF CORPORATION)
G-2: Thermal polymerization initiator (PERHEXYL O, manufactured by NOF CORPORATION)

### Synthesis of Compound Represented by Formula (1-5)

A 500-mL flask configured to include a stirrer, a thermometer, a nitrogen gas inlet tube, a discharge tube, and a heating jacket was used as a reactor, 120 g of polyethylene glycol #6000 and 300 g of toluene were introduced into the reactor, the mixture was stirred at 45° C. and a stirring rotation speed of 250 times/min, nitrogen was caused to flow at a rate of 100 mL/min, and the mixture was stirred for 30 minutes. Thereafter, temperature was lowered to 25° C., after completion of temperature lowering, 2.9 g of acryloyl chloride was added dropwise into the reactor, and the mixture was stirred for 30 minutes. Thereafter, 3.8 g of triethylamine was added dropwise thereto, and the mixture was stirred for 2 hours. Thereafter, temperature was raised to 45° C., and the mixture was caused to react for 2 hours. The reaction liquid was filtered, the filtrate was subjected to solvent removal, and a compound represented by the formula (1-5) was obtained.

### Synthesis of Compound Represented by Formula (1-6) and Compound Represented by Formula (1-7)

A compound represented by the formula (1-6) was obtained by a method similar to the method for synthesizing the compound represented by the formula (1-5), except that 120 g of polyethylene glycol #6000 was changed to polyoxyethylene polyoxypropylene glycol (“NEWPOL PE78” manufactured by Sanyo Chemical Industries, Ltd., 141 g). In addition, a compound represented by the formula (1-7) was obtained by a method similar to the method for synthesizing the compound represented by the formula (1-5), except that 120 g of polyethylene glycol #6000 was changed to 240 g of polyoxyethylene polyoxypropylene glycol (molecular weight 16000).

### Fabrication of Curable Composition and Cured Product

Each component was mixed at the blending ratio shown in Table 1, and a curable composition was obtained. Next, the curable composition was charged into a mold form (made of SUS plates) having a size of 5 cm×5 cm×0.2 mm, the top was covered with a SUS plate, and the curable composition was cured by heating under the conditions of 135° C. for 15 minutes, to obtain a cured product (film-shaped cured product having a thickness of 0.2 mm) of each of the curable compositions according to Examples 1 to 7.

### Polarization Treatment

The obtained film-shaped cured product of each Example was placed in insulating oil, and a polarization treatment was performed by applying an electric field of 10 kV/mm at normal temperature for 180 seconds.

### Measurement of Piezoelectric Constant d₃₃

For the film-shaped cured product after the polarization treatment of each Example, the piezoelectric constant d₃₃ was measured by using a d₃₃ meter manufactured by Lead Techno Co., Ltd. More specifically, the film-shaped cured product was sandwiched between terminals of a ϕ8-mm cylindrical-shaped piezometer at 1 N, and the piezoelectric constant d₃₃ was measured under the conditions of a preload force of 1 N and a load force of 1.5 N. Measurement of this d₃₃ was performed for five sheets of the film-shaped cured product after polarization treatment of each Example, the average value of the measured d₃₃ was determined, and the results are shown in Table 1.

### Measurement of Tensile Modulus

For the film-shaped cured product after polarization treatment of each Example, the tensile modulus at 25° C. was measured by using a tensile tester (“Autograph EZ-TEST EZ-S” manufactured by SHIMADZU CORPORATION). More specifically, for a film-shaped cured product having a size of 0.2 mm (thickness)×5 mm (width)×30 mm (length), the tensile modulus was measured on the basis of JIS K7161 under the conditions of a distance between chucks of 20 mm and a tensile speed of 5 mm/min. The results are shown in Table 1. When the measured tensile modulus is 50 MPa or less, it is recognized that deterioration of pliability can be suppressed.

### Measurement of Elongation at Break and Breaking Strength

For the film-shaped cured product after polarization treatment of each Example, the elongation at break and the breaking strength at 25° C. were measured by using a tensile tester (“Autograph EZ-TEST EZ-S” manufactured by SHIMADZU CORPORATION). More specifically, for the film-shaped cured product having a size of 0.2 mm (thickness)×5 mm (width)×30 mm (length), the elongation at break and the breaking strength were measured on the basis of JIS K7161 under the conditions of a distance between chucks of 20 mm and a tensile speed of 5 mm/min. The results are shown in Table 1.

TABLE 1

| | | Example 1 | Example 2 | Example 3 | Example 4 | Example 5 |
|---|---|---|---|---|---|---|
| Composition | A-1 | 78.20 | 76.50 | 72.25 | 78.20 | 76.50 |
| (parts by mass) | A-2 | 9.20 | 13.50 | 12.75 | 9.20 | 13.50 |
| | A-3 | 4.60 | — | — | 4.60 | — |
| | B-1 | — | — | — | 1.46 | — |
| | B-2 | — | 1.90 | — | — | 1.90 |
| | B-3 | 1.46 | — | 2.70 | — | — |
| | C-1 | 0.66 | 0.77 | — | 0.66 | 0.77 |
| | C-2 | — | — | 1.27 | — | — |
| | D-1 | 0.70 | 0.90 | 1.31 | 0.70 | 0.90 |
| | D-2 | 0.01 | 0.01 | — | 0.01 | 0.01 |
| | D-3 | 0.70 | 0.85 | 1.30 | 0.70 | 0.85 |
| | D-4 | 4.20 | 2.59 | 7.95 | 4.20 | 2.59 |
| | D-5 | — | 2.61 | — | — | 2.61 |
| | D-6 | — | — | — | — | — |
| | D-7 | — | — | — | — | — |
| | D-8 | — | — | — | — | — |
| | E-1 | — | 0.30 | 0.45 | — | 0.30 |
| | F-1 | 0.45 | 0.60 | 0.90 | — | 0.60 |
| | F-2 | — | — | — | 0.45 | — |
| | G-1 | 0.08 | 0.12 | 0.18 | 0.08 | — |
| | G-2 | — | — | — | — | 0.12 |

| | | | | | |
|---|---|---|---|---|---|
| Content of piezoelectric | 66 | 60 | 49 | 66 | 60 |
| particles (% by volume) | | | | | |
| Piezoelectric | 78 | 71 | 57 | 78 | 72 |
| constant d₃₃ (pC/N) | | | | | |
| Tensile modulus (MPa) | 38 | 22 | 28 | 38 | 27 |
| Elongation at break (%) | 25 | 43 | 118 | 25 | 45 |
| Breaking strength (MPa) | 2.8 | 2.9 | 2.6 | 2.9 | 3.1 |

| | | Example 6 | Example 7 | Example 8 | Example 9 | Example 10 |
|---|---|---|---|---|---|---|
| Composition | A-1 | 72.25 | 72.25 | 72.25 | 68.00 | 68.00 |
| (parts by mass) | A-2 | 12.75 | 8.50 | 8.50 | 12.00 | 8.00 |
| | A-3 | — | 4.25 | 4.25 | — | 4.00 |
| | B-1 | — | — | — | — | — |
| | B-2 | — | — | — | — | — |
| | B-3 | 2.70 | 2.70 | 2.70 | 3.60 | 3.60 |
| | C-1 | — | — | — | — | 1.50 |
| | C-2 | 1.27 | 1.25 | 1.25 | 1.70 | — |
| | D-1 | 1.31 | 1.31 | 1.31 | 1.74 | 1.80 |
| | D-2 | — | — | — | — | 0.02 |
| | D-3 | 1.30 | 1.30 | 1.30 | 1.70 | 1.70 |
| | D-4 | 7.95 | 6.00 | 6.50 | 8.20 | 6.00 |
| | D-5 | — | — | — | — | — |
| | D-6 | — | — | 1.45 | 2.40 | — |
| | D-7 | — | 1.95 | — | — | 2.30 |
| | D-8 | — | — | — | — | 2.30 |
| | E-1 | 0.45 | 0.45 | — | — | 0.30 |
| | F-1 | — | 0.90 | 0.90 | — | 1.20 |
| | F-2 | 0.90 | — | — | 1.20 | — |
| | G-1 | 0.18 | 0.18 | 0.18 | — | 0.24 |
| | G-2 | — | — | — | 0.24 | — |

| | | | | | |
|---|---|---|---|---|---|
| Content of piezoelectric | 49 | 49 | 49 | 40 | 40 |
| particles (% by volume) | | | | | |
| Piezoelectric | 61 | 56 | 59 | 50 | 49 |
| constant d₃₃ (pC/N) | | | | | |
| Tensile modulus (MPa) | 29 | 25 | 21 | 19 | 17 |
| Elongation at break (%) | 120 | 107 | 115 | 143 | 157 |
| Breaking strength (MPa) | 2.6 | 2.4 | 2.7 | 1.9 | 1.7 |

### Evaluation of Heat Resistance

For the film-shaped cured products after polarization treatment of Examples 1 to 3, the 5% weight loss temperature and the weight loss ratio after being maintained at 150° C. for 1 hour were measured in order to evaluate heat resistance. Specifically, the 5% weight loss temperature was determined by using a simultaneous thermogravimetric differential thermal analyzer (manufactured by Hitachi High-Tech Science Corporation, TG/DTA6300), by raising the temperature from 25° C. to 500° C. at a temperature increase rate of 10° C./min under the conditions of a nitrogen flow of 400 mL/min and measuring the temperature (° C.) at the time when the weight of the film-shaped cured product was decreased by 5% with respect to the weight of the film-shaped cured product before temperature increase. Furthermore, the weight loss rate after being maintained at 150° C. for 1 hour was measured by using the above-described simultaneous thermogravimetric differential thermal analyzer, when raising the temperature from 25° C. to 150° C. at a temperature increase rate of 10° C./min under the conditions of a nitrogen flow of 400 mL/min, and maintaining the film-shaped cured product at 150° C. for 1 hour, as a reduction rate (% by weight) of the weight of the film-shaped cured product after being maintained at 150° C./1 hour with respect to the weight of the film-shaped cured product before temperature increase. The results are shown in Table 2.

TABLE 2

| | Example 1 | Example 2 | Example 3 |
|---|---|---|---|
| 5% weight loss temperature | 402.8 | 406.6 | 399.3 |
| Weight loss rate (% by weight) | 0.08 | 0.02 | 0.05 |
| after being maintained at | | | |
| 150° C./1 hour | | | |

### Evaluation of Change in Piezoelectric Characteristics in High-Temperature Environment

For the film-shaped cured products after polarization treatment of Examples 2, 3 and 9, each of the film-shaped cured products was left to stand still in a constant-temperature chamber at 120° C. for 96 hours in order to evaluate the piezoelectric characteristics in a high-temperature environment. For each of the film-shaped cured products, the value (%) of the piezoelectric constant d₃₃ after 96 hours was determined relative to the piezoelectric constant d₃₃ before being placed in the constant-temperature chamber, which was taken as 100%. Incidentally, the method for measuring the piezoelectric constant d₃₃ is similar to the method described above. The results are shown in Table 3.

TABLE 3

| | Example 2 | Example 3 | Example 9 |
|---|---|---|---|
| Piezoelectric constant d₃₃ (%) | 98.3 | 96.3 | 98.7 |
| after 96 hours | | | |

1. A curable composition comprising:
piezoelectric particles; and
a compound represented by the following formula (1): 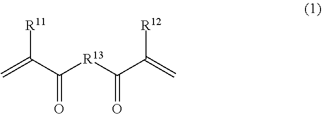
wherein R¹¹ and R¹² each independently represent a hydrogen atom or a methyl group, and R¹³ represents a divalent group having a polyoxyalkylene chain.

2. The curable composition according to claim 1, wherein a content of the piezoelectric particles is 35% by volume or more based on a total amount of the curable composition.

3. The curable composition according to claim 1, wherein the polyoxyalkylene chain comprises an oxyethylene group.

4. The curable composition according to claim 1, wherein the polyoxyalkylene chain comprises an oxypropylene group.

5. The curable composition according to claim 1, wherein the polyoxyalkylene chain is a copolymer chain comprising an oxyethylene group and an oxypropylene group.

6. The curable composition according to claim 5, wherein the copolymer chain is a random copolymer chain.

7. The curable composition according to claim 1, wherein the compound represented by the formula (1) has a weight average molecular weight of 5000 or more.

8. The curable composition according to claim 1, wherein the compound represented by the formula (1) has a viscosity at 25° C. of 1000 Pa·s or lower.

9. The curable composition according to claim 1, further comprising a compound represented by the following formula (2): 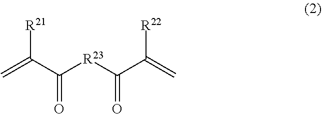
wherein R²¹ and R²² each independently represent a hydrogen atom or a methyl group, and R²³ represents a divalent group having a poly (meth) acrylate chain.

10. The curable composition according to claim 1, further comprising a compound represented by the following formula (3): 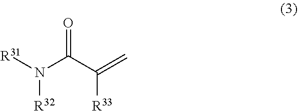
wherein R³¹ and R³² each independently represent a hydrogen atom or a monovalent organic group and may be bonded to each other to form a ring, and R³³ represents a hydrogen atom or a methyl group.

11. A cured product of the curable composition according to claim 1.

12. A piezoelectric element comprising the cured product according to claim 11.
